(19) United States
(12) Patent Application Publication
(10) Pub. No.: US 2021/0029815 A1
(43) Pub. Date: Jan. 28, 2021

(54) NANOSECOND PULSER RF ISOLATION

(71) Applicant: Eagle Harbor Technologies, Inc., Seattle, WA (US)

(72) Inventors: Christopher Bowman, Seattle, WA (US); Connor Liston, Seattle, WA (US); Nicolas A. Yang, Seattle, WA (US); Kenneth Miller, Seattle, WA (US); Ilia Slobodov, Seattle, WA (US); Timothy Ziemba, Bainbridge Island, WA (US)

(21) Appl. No.: 16/919,085

(22) Filed: Jul. 1, 2020

Related U.S. Application Data
(60) Provisional application No. 62/869,999, filed on Jul. 2, 2019.

(51) Int. Cl. H05H 1/46; H01J 37/32

(52) U.S. Cl. CPC H05H 1/46; H01J 37/3244; H01L 21/3065; H01J 37/32091; H01J 37/321; H01J 37/32155

(57) ABSTRACT

Some embodiments include a plasma system that includes a plasma chamber; an RF driver driving RF bursts into the plasma chamber with an RF frequency greater than 2 MHz; a nanosecond pulser driving pulses into the plasma chamber with a pulse repetition frequency a peak voltage, the pulse repetition frequency being less than the RF frequency and the peak voltage being greater than 2 kV; a first filter disposed between the RF driver and the plasma chamber; and a second filter disposed between the nanosecond pulser and the plasma chamber.

### BACKGROUND

The semiconductor device fabrication process uses plasma processing at different stages to make semiconductor devices, which may include a microprocessor, a memory chip, and other types integrated circuits and devices. Plasma processing involves energizing a gas mixture by imparting energy to the gas molecules by introducing RF (radio frequency) energy into the gas mixture. This gas mixture is typically contained in a vacuum chamber, referred to as a plasma chamber, and the RF energy is typically introduced into the plasma chamber through electrodes.

In a typical plasma process, the RF generator generates power at a radio frequency, which is broadly understood as being within the range of 3 kHz and 300 GHz, and this power is transmitted through RF cables and networks to the plasma chamber. In order to provide efficient transfer of power from the RF generator to the plasma chamber, an intermediary circuit is used to match the fixed impedance of the RF generator with the variable impedance of the plasma chamber. Such an intermediary circuit is commonly referred to as an RF impedance matching network, or more simply as an RF matching network.

### SUMMARY

Embodiments of the invention include a plasma system. The plasma system includes a plasma chamber; an RF driver configured to drive RF bursts into the plasma chamber with an RF frequency; a nanosecond pulser configured to drive pulses into the plasma chamber with a pulse repetition frequency, the pulse repetition frequency being less than the RF frequency; a high pass filter disposed between the RF driver and the plasma chamber; and a low pass filter disposed between the nanosecond pulser and the plasma chamber.

In some embodiments, the RF driver may include a variable impedance RF driver. In some embodiments, the RF driver may include a full-bridge (or half-bridge) switching circuit, a resonate circuit, and/or a transformer.

In some embodiments, either or both the RF driver and/or the nanosecond pulser may include a resistive output stage and/or an energy recovery circuit.

In some embodiments, the high pass filter may include a capacitor. In some embodiments, the low pass filter may include an inductor. In some embodiments, the RF driver may comprise a nanosecond pulser.

Some embodiments include a plasma system comprising: a plasma chamber; an RF driver driving RF bursts into the plasma chamber with an RF frequency greater than 2 MHz; a nanosecond pulser driving pulses into the plasma chamber with a pulse repetition frequency and a peak voltage, the pulse repetition frequency being less than the RF frequency and the peak voltage being greater than 2 kV; a first filter disposed between the RF driver and the plasma chamber; and a second filter disposed between the nanosecond pulser and the plasma chamber. In some embodiments, the pulse repetition frequency is greater than 10 kHz.

In some embodiments, the first filter comprises a high pass filter. In some embodiments, first filter includes a capacitor in series with the RF driver and the plasma chamber, the capacitor includes a capacitance less than about 500 pH. In some embodiments, first filter includes an inductor coupled with an output of the RF driver and ground.

In some embodiments, the second filter comprises a low pass filter. In some embodiments, the second filter includes an inductor in series with the nanosecond pulser and the plasma chamber, the inductor having an inductance less than about 50 μH. In some embodiments, the second filter includes a capacitor in coupled with an output of the nanosecond pulser and ground.

In some embodiments, the plasma chamber comprises an antenna electrically coupled with the RF driver. In some embodiments, the plasma chamber comprises a cathode electrically coupled with the RF driver. In some embodiments, the plasma chamber comprises a cathode electrically coupled with the nanosecond pulser.

Some embodiments include a plasma system comprising: a plasma chamber with an antenna and a cathode; an RF driver electrically coupled with the antenna, the RF driver producing RF bursts in the plasma chamber with an RF frequency greater than about 2 MHz; a nanosecond pulser electrically coupled with the cathode, the nanosecond pulser producing pulses into the plasma chamber with a pulse repetition frequency less than the RF frequency and with a voltage greater than 2 kV; a capacitor disposed between the RF driver and the antenna; and an inductor disposed between the nanosecond pulser and the cathode.

In some embodiments, the capacitor has a capacitance less than about 100 pF. In some embodiments, the inductor has an inductance less than about 10 nH. In some embodiments, the pulse repetition frequency is greater than 10 kHz.

Some embodiments include a plasma system comprising: a plasma chamber comprising a cathode; an RF driver electrically coupled with the cathode, the RF driver producing RF bursts in the plasma chamber with an RF frequency greater than about 2 MHz; a nanosecond pulser electrically coupled with the cathode, the nanosecond pulser producing pulses into the plasma chamber with a pulse repetition frequency less than the RF frequency and with a voltage greater than 2 kV; a capacitor disposed between the RF driver and the cathode; and an inductor disposed between the nanosecond pulser and the cathode.

In some embodiments, the capacitor has a capacitance less than about 100 pF. In some embodiments, the inductor has an inductance less than about 10 nH. In some embodiments, the pulse repetition frequency is greater than 10 kHz.

These embodiments are mentioned not to limit or define the disclosure, but to provide examples to aid understanding thereof. Additional embodiments are discussed in the Detailed Description, and further description is provided there. Advantages offered by one or more of the various embodiments may be further understood by examining this specification or by practicing one or more embodiments presented.

### BRIEF DESCRIPTION OF THE FIGURES

These and other features, aspects, and advantages of the present disclosure are better understood when the following Detailed Description is read with reference to the accompanying drawings.

FIG. 1A shows a pulse from a nanosecond pulser.

FIG. 1B shows a burst of pulses from a nanosecond pulser.

FIG. 2A shows an RF burst from an RF Driver.

FIG. 2B shows a plurality of RF bursts from an RF driver.

FIG. 3 is a schematic representation of a plasma system with a filtered variable impedance RF driver and a filtered nanosecond pulser bias generator according to some embodiments.

FIG. 4 is a schematic representation of a plasma system with a filtered variable impedance RF driver and a filtered nanosecond pulser bias generator according to some embodiments.

FIG. 5 is a schematic representation of a plasma system with a filtered variable impedance RF driver and a filtered nanosecond pulser bias generator according to some embodiments.

FIG. 6 is a schematic representation of a plasma system with a filtered variable impedance RF driver and a filtered nanosecond pulser bias generator according to some embodiments.

FIG. 7 is a circuit diagram of a plasma system according to some embodiments.

FIG. 8 is a circuit diagram of an RF driver according to some embodiments.

FIG. 9 is a circuit diagram of an RF driver according to some embodiments.

FIG. 10 is a waveform produced by a plasma system according to some embodiments.

FIG. 11 is a waveform produced by a plasma system according to some embodiments.

FIG. 12 is a waveform produced by a plasma system according to some embodiments.

FIG. 13 is a waveform produced by a plasma system according to some embodiments.

### DETAILED DESCRIPTION

A plasma system is disclosed. The plasma system includes a plasma chamber with an RF driver that drives RF bursts into the plasma chamber and a nanosecond pulser that drives pulses into the plasma chamber. The pulse repetition frequency of the pulses may be less than the RF frequency of the RF bursts. The plasma system may also include a high pass filter disposed between the RF driver and the plasma chamber and a low pass filter disposed between the nanosecond pulser and the plasma chamber. In some embodiments,

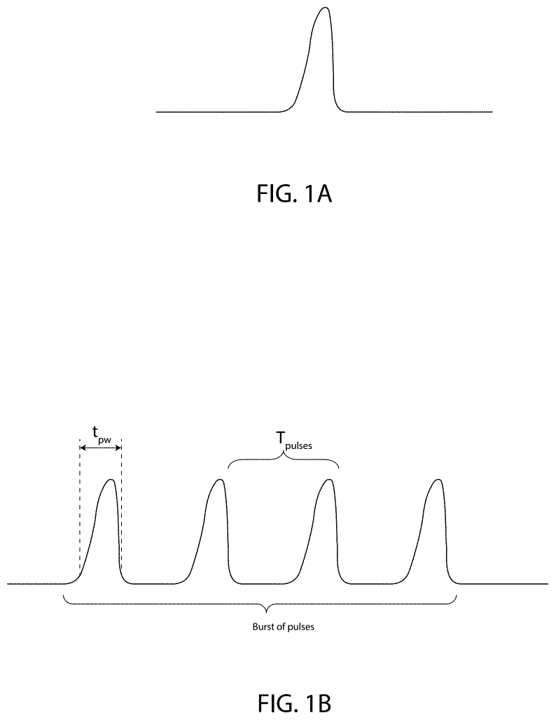

FIG. 1A shows an example pulse from a nanosecond pulser. FIG. 1B shows a burst of pulses from a nanosecond pulser. A pulse burst may include a plurality of pulses within a short time frame. The pulses within a pulse burst can have a pulse repetition frequency of about 10 kHz, 50 kHz, 100 kHz, 500 kHz, 1 MHz, etc. Each pulse may have a pulse width of t_{pw}. And the pulse repetition frequency may be the inverse of the pulse-to-pulse period Tₚᵤₗₛₑ.

In some embodiments, the pulses may have a high peak voltage (e.g., voltages greater than 1 kV, 10 kV, 20 kV, 50 kV, 100 kV, etc.), a high pulse repetition frequency (e.g., frequencies greater than 1 kHz, 10 kHz, 100 kHz, 200 kHz, 500 kHz, 1 MHz, etc.), a fast rise time (e.g., rise times less than about 1 ns, 10 ns, 50 ns, 100 ns, 250 ns, 500 ns, 1,000 ns, etc.), a fast fall time (e.g., fall times less than about 1 ns, 10 ns, 50 ns, 100 ns, 250 ns, 500 ns, 1,000 ns, etc.) and/or short pulse widths (e.g., pulse widths less than about 1,000 ns, 500 ns, 250 ns, 100 ns, 20 ns, etc.).

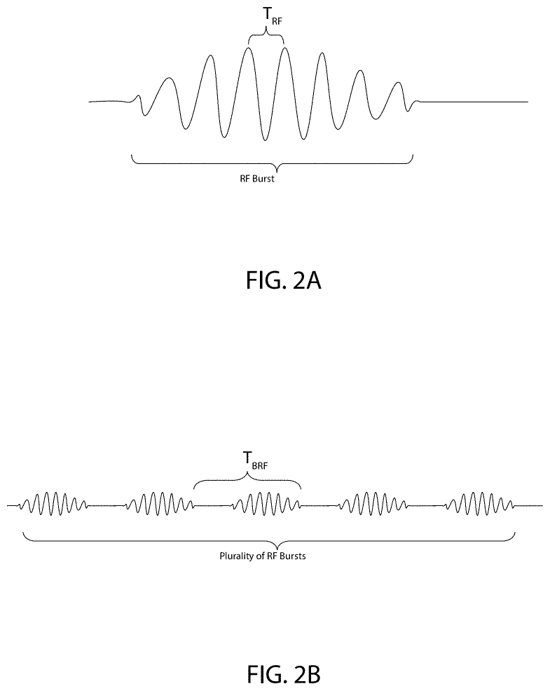

FIG. 2A shows an example RF burst from an RF driver. The RF burst may have a frequency that is in the inverse RF period T_{RF}.

FIG. 2B shows an example plurality of RF bursts from an RF driver. Each RF burst can include a sinusoidal RF burst with an RF frequency of 200 kHz and 800 MHz such as, for example, 2 MHz, 13.56 MHz, 27 MHz, 60 MHz, and 80 MHz. The RF burst repetition frequency may be the inverse of the burst-to-burst period T^{BRF}. In some embodiments, the RF burst repetition frequency (e.g., the frequency of RF bursts) may be about 10 kHz, 50 Hz, 100 kHz, 500 kHz, 1 MHz, etc. such as, for example, 400 kHz. In some embodiments, the RF driver may provide a continuous sinusoidal waveform.

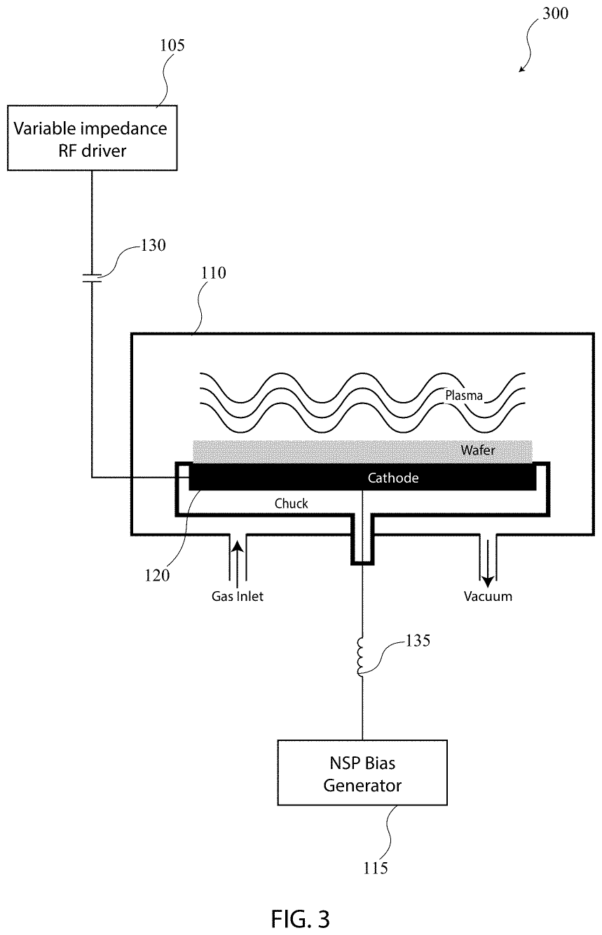

FIG. 3 is a schematic representation of a plasma system 300 according to some embodiments. In some embodiments, the plasma system 300 may include a plasma chamber 110 with a RF driver 105 and a nanosecond pulser bias generator 115 according to some embodiments. The RF driver 105 can be coupled with the cathode 120 located within the plasma chamber 110. The nanosecond pulser bias generator 115 can be coupled with the cathode 120 located within the plasma chamber 110. In some embodiments, the cathode 120 may be part of or coupled with a electrostatic chuck.

In some embodiments, the plasma chamber 110 may include a vacuum pump that maintains vacuum conditions in the plasma chamber 110. The vacuum pump, for example, may be connected to the plasma chamber 110 with a specialized hose or stainless steel piping. The vacuum pump may be controlled manually or automatically by a machine by either a relay or pass-through plug on the machine.

In some embodiments, the plasma chamber 110 may include an input gas source that may introduce gas (or a mixture of input gases) into the chamber before, after, or when the RF power is supplied. The ions in the gas create the plasma and the gas is evacuated through the vacuum pump.

In some embodiments, the plasma system may include a plasma deposition system, plasma etch system, or plasma sputtering system. In some embodiments, the capacitance between the chuck and wafer may have a capacitance less than about 1000 nF, 500 nF, 200 nF, 100 nF, 50 nF, 10 nF, 5000 pF, 1000 pF, 100 pF, etc.

The RF driver 105 may include any type of device that generates RF power that is applied to the cathode 120. The RF driver 105, for example, may include a nanosecond pulser, a resonant system driven by a half bridge or full bridge circuit, an RF amplifier, a non-linear transmission line, an RF plasma generator, a variable impedance RF driver, etc. In some embodiments, the RF driver 105 may include a matching network.

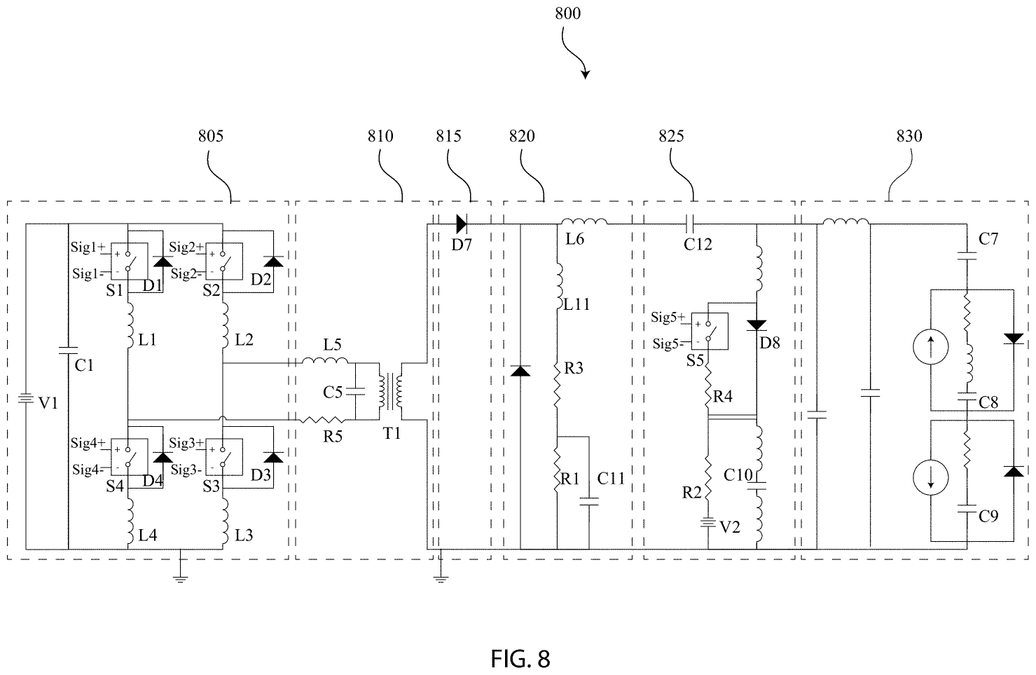

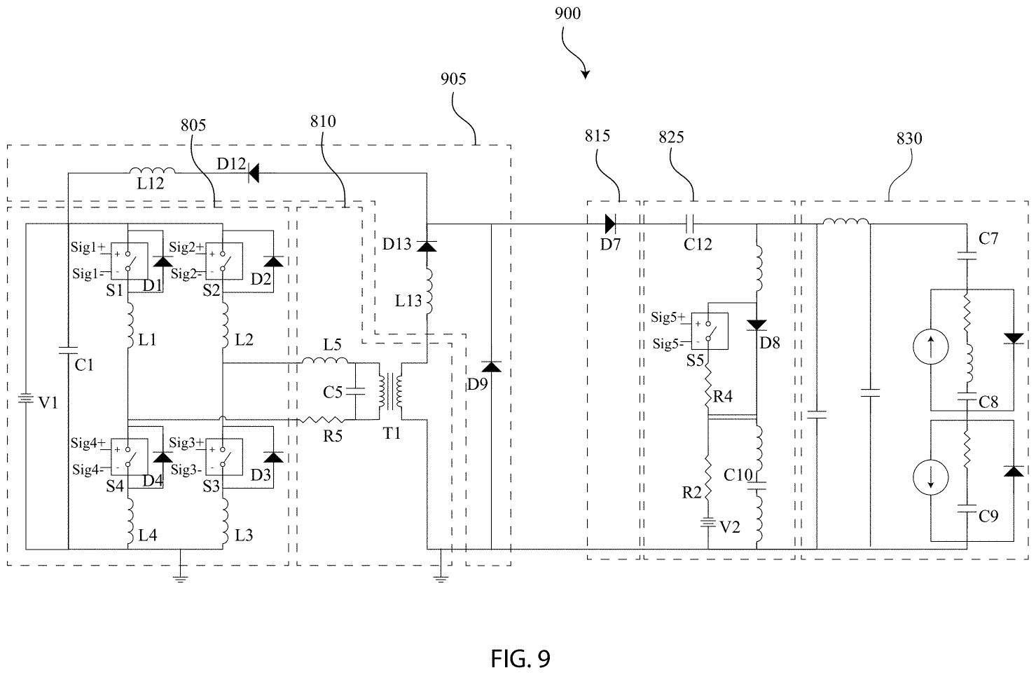

In some embodiments, the RF driver 105 may include any or all portions of the RF driver and chamber circuit 800 shown in FIG. 8 and/or the RF driver and chamber circuit 900 shown in FIG. 9.

In some embodiments, the RF driver 105 may include one or more RF drivers that may generate an RF power signal having a plurality of different RF frequencies such as, for example, 2 MHz, 13.56 MHz, 27 MHz, 60 MHz, and 80 MHz. Typical RF frequencies, for example, may include frequencies between 200 kHz and 800 MHz In some embodiments, the RF driver 105 may create and sustain a plasma within the plasma chamber 110. The RF driver 105, for example, provides an RF signal to the cathode 120 (and/or the antenna 180, see below) to excite the various gases and/or ions within the chamber to create the plasma.

In some embodiments, the RF driver 105 may be coupled with or may include an impedance matching circuit, which may match the non-standard output impedance of the RF driver 105 to the industry standard characteristic impedance of the coaxial cable of 50 ohms or any cable.

In some embodiments the RF driver 105 may include all or any portion of any device described in U.S. patent application Ser. No. 16/697,173, titled “Variable Output Impedance RF Generator,” which is incorporated into this disclosure for all purposes,

The nanosecond pulser bias generator 115 (or digital pulser) may include one or more nanosecond pulsers. In some embodiments the nanosecond pulser bias generator 115 may include all or any portion of any device described in U.S. patent application Ser. No. 14/542,487, titled “High Voltage Nanosecond Pulser,” which is incorporated into this disclosure for all purposes.

In some embodiments the nanosecond pulser bias generator 115 may include all or any portion of any device described in U.S. patent application Ser. No. 14/635,991, titled “Galvanically Isolated Output Variable Pulse Generator Disclosure,” which is incorporated into this disclosure for all purposes,

In some embodiments the nanosecond pulser bias generator 115 may include all or any portion of any device described in U.S. patent application Ser. No. 14/798,154, titled “High Voltage Nanosecond Pulser With Variable Pulse Width and Pulse Repetition Frequency,” which is incorporated into this disclosure for all purposes.

In some embodiments the nanosecond pulser bias generator 115 may include all or any portion of any device described in U.S. patent application Ser. No. 15/941,731, titled “High Voltage Resistive Output Stage Circuit,” which is incorporated into this disclosure for all purposes.

In some embodiments the nanosecond pulser bias generator 115 may include all or any portion of any device described in U.S. patent application Ser. No. 16/114,195, titled “Arbitrary Waveform Generation Using Nanosecond Pulses,” which is incorporated into this disclosure for all purposes.

In some embodiments the nanosecond pulser bias generator 115 may include all or any portion of any device described in U.S. patent application Ser. No. 16/523,840, titled “Nanosecond Pulser Bias Compensation,” which is incorporated into this disclosure for all purposes.

In some embodiments the nanosecond pulser bias generator 115 may include all or any portion of any device described in U.S. patent application Ser. No. 16/737,615, titled “Efficient Energy Recovery In A Nanosecond Pulser Circuit,” which is incorporated into this disclosure for all purposes.

In some embodiments, the nanosecond pulser bias generator 115 may generate pulses with voltage amplitudes greater than about 1 kV, 5 kV, 10 kV, 20 kV, 30 kV, 40 kV, etc. In some embodiments, the nanosecond pulser bias generator 115 may switch with a pulse repetition frequency up to about 2,000 kHz. In some embodiments, the nanosecond pulser may switch with a pulse repetition frequency of about 400 kHz. In some embodiments, the nanosecond pulser bias generator 115 may provide single pulses of varying pulse widths from about 2000 ns to about 1 nanosecond. In some embodiments, the nanosecond pulser bias generator 115 may switch with a pulse repetition frequency greater than about 10 kHz. In some embodiments, the nanosecond pulser bias generator 115 may operate with rise times less than about 20 ns.

In some embodiments, the nanosecond pulser bias generator 115 can produce pulses from the power supply with voltages greater than 2 kV, with rise times less than about 80 ns, and with a pulse repetition frequency greater than about 10 kHz.

In some embodiments, the nanosecond pulser bias generator 115 may include one or more solid state switches (e.g., solid state switches such as, for example, IGBTs, a MOSFETs, SiC MOSFETs, SiC junction transistors, FETs, SiC switches, GaN switches, photoconductive switches, etc.), one or more snubber resistors, one or more snubber diodes, one or more snubber capacitors, and/or one or more freewheeling diodes. The one or more switches and or circuits can be arranged in parallel or series. In some embodiments, one or more nanosecond pulsers can be ganged together in series or parallel to form the nanosecond pulser bias generator 115. In some embodiments, a plurality of high voltage switches may be ganged together in series or parallel to form the nanosecond pulser bias generator 115.

In some embodiments, the nanosecond pulser bias generator 115 may include circuitry to remove charge from a capacitive load in fast time scales such as, for example, a resistive output stage, a sink, or an energy recovery circuit. In some embodiments, the charge removal circuitry may dissipate charge from the load, for example, on fast time scales (e.g., 1 ns, 10 ns, 50 ns, 100 ns, 250 ns, 500 ns, 1,000 ns, etc. time scales).

In some embodiments, a DC bias power supply stage may be included to bias the output voltage to the cathode 120 either positively or negatively. In some embodiments, a capacitor may be used to isolate/separate the DC bias voltage from the charge removal circuitry or other circuit elements. It may also allow for a potential shift from one portion of the circuit to another. In some applications the potential shift may be used to hold a wafer in place.

In some embodiments, the RF driver 105 may produce RF bursts with an RF frequency greater than the pulse repetition frequency of the pulses produced by the nanosecond pulser bias generator 115.

In some embodiments, a capacitor 130 may be disposed (e.g., in series) between the RF driver 105 and the cathode 120. The capacitor 130 may be used, for example, to filter low frequency signals from the nanosecond pulser bias generator 115. These low frequency signals, for example, may have frequencies (e.g., the majority of spectral content) of about 100 kHz and 10 MHz such as, for example, about 10 MHz. The capacitor 130, for example, may have values of about 1 pF to 1 nF such as, for example, less than about 100 pF.

In some embodiments, an inductor 135 may disposed (e.g., in series) between the nanosecond pulser bias generator 115 and the cathode 120. The inductor 135 may be used, for example, to filter high frequency signals from the RF driver 105. These high frequency signals, for example, may have frequencies from about 1 MHz to 200 MHz such as, for example, greater than about 1 MHz or 10 MHz. The inductor 135, for example, may have values from about 10 nH to 10 μH such as, for example, greater than about 1 μH. In some embodiments, the inductor 135 may have a low coupling capacitance across it. In some embodiments, the coupling capacitance may be less than 1 nF

In some embodiments, either or both the capacitor 130 and the inductor 135 may isolate RF bursts produced by the RF driver 105 from the pulses produce by the nanosecond pulser bias generator 115. For example, the capacitor 130 may isolate the pulses produced by the nanosecond pulser bias generator 115 from the RF bursts produced by the RF driver 105. The inductor 135 may isolate the RF bursts produced by the RF driver 105 from the pulses produced by the nanosecond pulser bias generator 115.

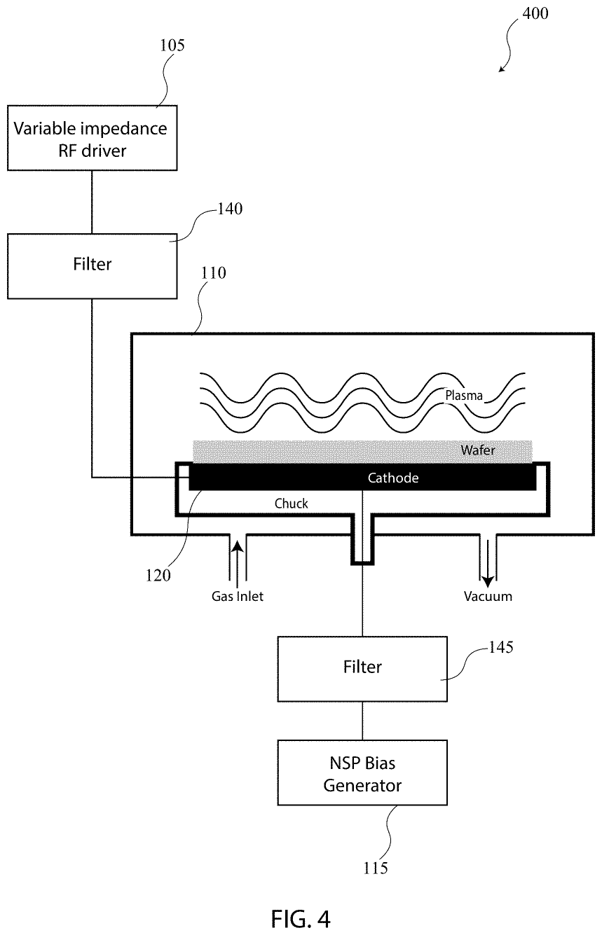

FIG. 4 is a schematic representation of a plasma system 400. Plasma system 400 includes plasma chamber 110 with a filtered RF driver 105 and a nanosecond pulser bias generator 115 according to some embodiments. The plasma system 400 may be similar to the plasma system 300 in FIG. 3. In this embodiment, a filter 140 may replace the capacitor 130 and/or the filter 145 may replace the inductor 135. The filters alternately protect the variable impedance RF driver from the pulses produced by the nanosecond pulser bias generator, and the nanosecond pulser bias generator from the RF bursts produced by the variable impedance RF driver. Numerous different filters may be employed to accomplish this. In some embodiments, the filters may let less than 30% of the attenuated signal pass through into the protected generator. For example, the filter protecting the NSP Bias Generator may be designed to let less than 30% of the signal (measured in power) produced by the variable impedance RF driver pass through it and into the nanosecond pulser bias generator.

In some embodiments, the RF driver 105 may produce RF bursts with an RF frequency, fₚ, greater than pulse repetition frequency in each RF burst produced by the nanosecond pulser bias generator 115.

In some embodiments, the filter 140 may be disposed (e.g., in series) between the RF driver 105 and the cathode 120. The filter 140 may be a high pass filter that allows high frequency RF bursts with frequencies from about 1 MHz to 200 MHz such as, for example, about 1 MHz or 10 MHz. The filter 140, for example, may include any type of filter that can pass these high frequency signals.

In some embodiments, the filter 145 may be disposed (e.g., in series) between the nanosecond pulser bias generator 115 and the cathode 120. The filter 145 may be a low pass filter that allows low frequency pulses with frequencies less than about 100 kHz and 10 MHz such as, for example, about 10 MHz. The filter 145, for example, may include any type of filter that can pass these low frequency signals.

In some embodiments, either or both the filter 140 and the filter 145 may isolate the RF bursts produced by the RF driver 105 from the pulses produced by the nanosecond pulser bias generator 115. For example, the filter 140 may isolate the pulses produced by the nanosecond pulser bias generator 115 from the RF bursts produced by the RF driver 105. The filter 145 may isolate the RF bursts produced by the RF driver 105 from the pulses produced by the nanosecond pulser bias generator 115.

In some embodiments, the filter 140 may include a high-pass filter such as, for example, a high-pass capacitor placed in series with the RF driver 105 and/or a high-pass inductor connected to ground. The high-pass inductor may, for example, include an inductor with an inductance of about 20 nH to about 50 μH. As another example, the high-pass inductor may include a high-pass inductor with an inductance of about 200 nH to about 5 μH. As another example, the high-pass inductor may include an inductor with an inductance of about 500 nH to about 1 μH. As another example, the a high-pass inductor may include an inductor with an inductance of about 800 nH.

The high-pass capacitor may, for example, include an capacitor with an capacitance of about 10 pF to about 10 nF. As another example, the high-pass capacitor may include a high-pass capacitor with an capacitance of about 50 pF to about 1 nF. As another example, the high-pass capacitor may include an capacitor with an capacitance of about 100 pF to about 500 pF. As another example, the a high-pass may include an capacitor with an capacitance of about 320 pF.

In some embodiments, the filter 145 may include a low-pass filter such as, for example, a low-pass inductor placed in series with the nanosecond pulser bias generator 115 and/or a low-pass capacitor connected to ground. The low-pass inductor may, for example, include an inductor with an inductance of about 0.5 μH to about 500 μH. As another example, the low-pass inductor may include a low-pass inductor with an inductance of about 1 μH to about 100 μH. As another example, the low-pass inductor may include an inductor with an inductance of about 2 μH to about 10 μH. As another example, the a low-pass may include an inductor with an inductance of about 2.5 nH.

The low-pass capacitor may, for example, include an capacitor with an capacitance of about 10 pF to about 10 nF. As another example, the low-pass capacitor may include a high-pass capacitor with an capacitance of about 50 pF to about 1 nF. As another example, the low-pass capacitor may include an capacitor with an capacitance of about 100 pF to about 500 pF. As another example, the a low-pass may include an capacitor with an capacitance of about 250 pF.

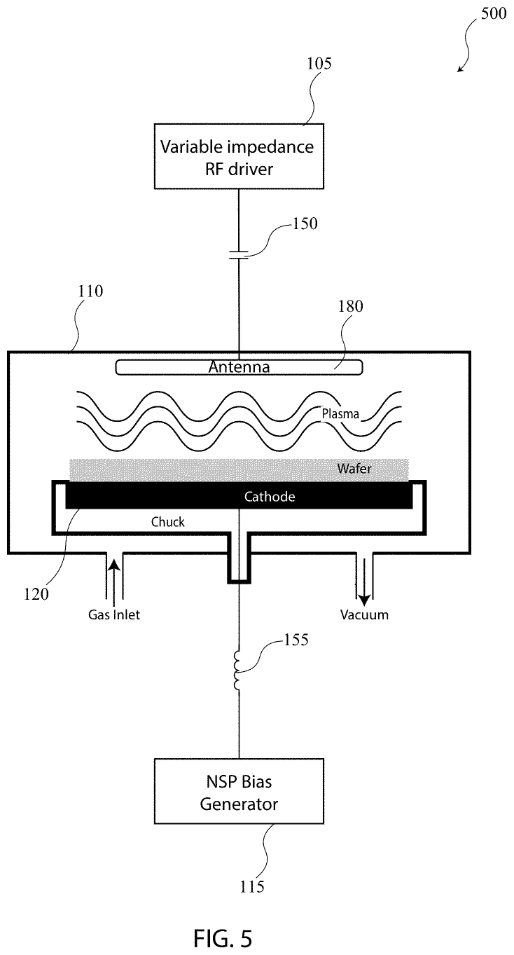

FIG. 5 is a schematic representation of a plasma system 500. The plasma system 500 may include a plasma chamber 110 with a filtered RF driver 105 and a filtered nanosecond pulser bias generator 115 according to some embodiments.

The RF driver 105 may include any type of device that generates RF power that is applied to the antenna 180. In some embodiments, the RF driver 105 may include one or more RF drivers that may generate an RF power signal having a plurality of different RF frequencies such as, for example, 2 MHz, 13.56 MHz, 27 MHz, and 60 MHz.

In some embodiments, the RF driver 105 may be coupled with or may include an impedance matching circuit, which may match the non-standard output impedance of the RF driver 105 to the industry standard characteristic impedance of the coaxial cable of 50 ohms or any cable.

In some embodiments, the RF driver 105 may include one or more nanosecond pulser.

In some embodiments, the nanosecond pulser bias generator 115 is described in conjunction with FIG. 3.

In some embodiments, the RF driver 105 may produce pulses with an RF frequency greater than the pulse repetition frequency of the pulses produced by the nanosecond pulser bias generator 115.

In some embodiments, a capacitor 150 may be disposed (e.g., in series) between the RF driver 105 and the antenna 180. The capacitor 150 may be used, for example, to filter low frequency signals from the nanosecond pulser bias generator 115. These low frequency signals, for example, may have frequencies less than about 100 kHz and 10 MHz such as, for example, about 10 MHz. The capacitor 150, for example, may have values of about 1 pF to 1 nF such as, for example, less than about 100 pF.

In some embodiments, an inductor 155 may disposed (e.g., in series) between the nanosecond pulser bias generator 115 and the cathode 120. The inductor 135 may be used, for example, to filter high frequency signals from the RF driver 105. These high frequency signals, for example, may have frequencies greater than about 1 MHz to 200 MHz such as, for example, greater than about 1 MHz or 10 MHz. The inductor 155, for example, may have values less than about 10 nH to 10 μH such as, for example, greater than about 1 μH. In some embodiments, the inductor 155 may have a low coupling capacitance across it.

In some embodiments, either or both the capacitor 150 and the inductor 155 may isolate the RF bursts produced by the RF driver 105 from the pulses produced by the nanosecond pulser bias generator 115. For example, the capacitor 150 may isolate the pulses produced by the nanosecond pulser bias generator 115 from the RF bursts produced by the RF driver 105. The inductor 155 may isolate the RF bursts produced by the RF driver 105 from the pulses produced by the nanosecond pulser bias generator 115.

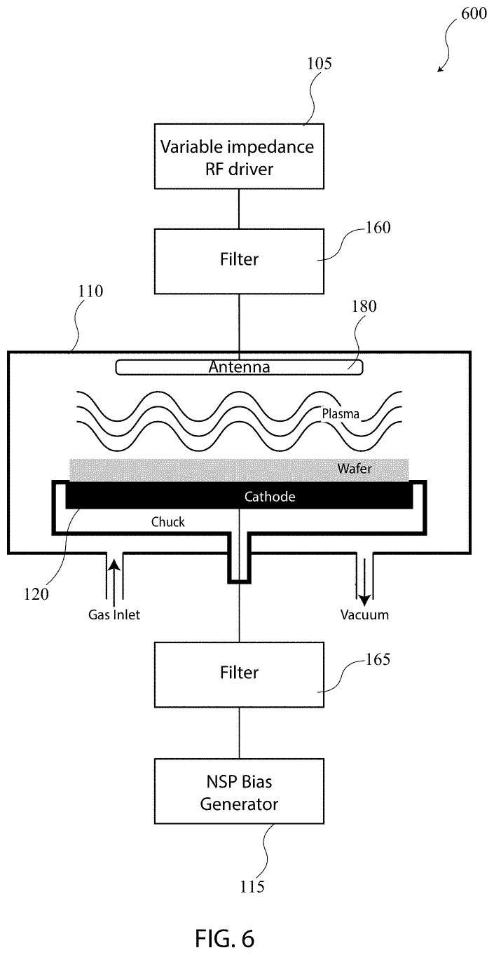

FIG. 6 is a schematic representation of a plasma system 600 with a plasma chamber 110 with a filtered RF driver 105 and a filtered nanosecond pulser bias generator 115 according to some embodiments. The plasma system 600 may be similar to the plasma system 500 in FIG. 5. In this embodiment, a filter 160 may replace the capacitor 150 and/or the filter 165 may replace the inductor 135.

In some embodiments, the RF driver 105 may produce RF bursts with an RF frequency greater than the pulse repetition frequency of the pulses produced by the nanosecond pulser bias generator 115.

In some embodiments, the filter 160 may be disposed (e.g., in series) between the RF driver 105 and the cathode 120. The filter 160 may be a high pass filter that allows high frequency RF bursts with frequencies greater than about 1 MHz to 200 MHz such as, for example, greater than about 1 MHz or 10 MHz. The filter 160, for example, may include any type of filter that can pass these high frequency signals.

In some embodiments, the filter 165 may be disposed (e.g., in series) between the nanosecond pulser bias generator 115 and the cathode 120. The filter 165 may be a low pass filter that allows low frequency pulses with frequencies less than about 100 kHz and 10 MHz such as, for example, about 10 MHz. The filter 165, for example, may include any type of filter that can pass these low frequency signals.

In some embodiments, either or both the filter 160 and the filter 165 may isolate the RF bursts produced by the RF driver 105 from the pulses produced by the nanosecond pulser bias generator 115. For example, the filter 160 may isolate the pulses produced by the nanosecond pulser bias generator 115 from the RF bursts produced by the RF driver 105. The filter 165 may isolate the RF bursts produced by the RF driver 105 from the pulses produced by the nanosecond pulser bias generator 115.

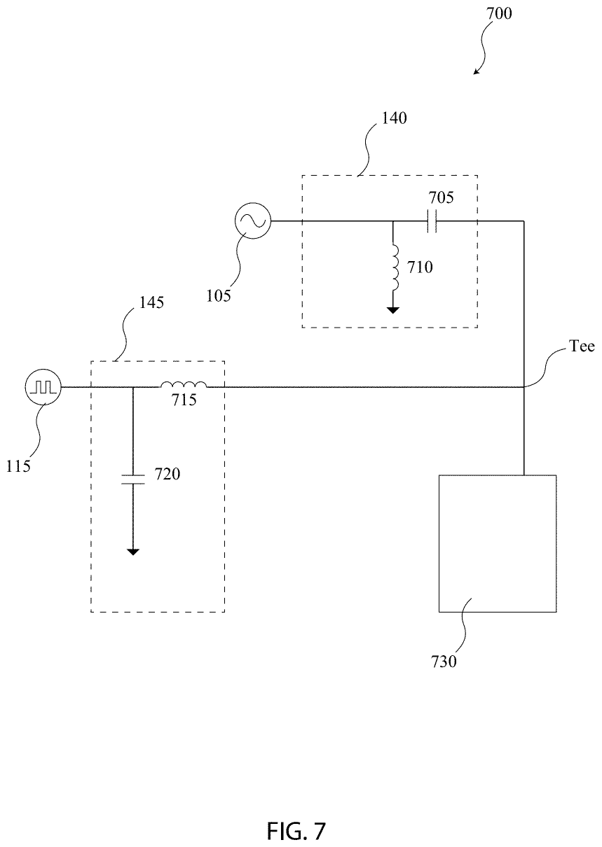

FIG. 7 is a circuit diagram of a plasma system 700 according to some embodiments. The plasma system 700 includes an RF driver 105 and nanosecond pulser bias generator 115. The RF driver 105 and the nanosecond pulser bias generator 115 are coupled with a load 730 at a Tee in the circuit.

The load 730 may include any type of load. For example, the load 730 may be a low capacitive load such as, for example, a load with a capacitance less than about 1 nF to about 10 nF or 100 pF to 100 nF or 10 pF to 1,000 nF. As another example, the load 730 may include the plasma chamber 110. As another example, the load 730 may include the plasma and chamber 830. As another example, the load 730 may include any dielectric barrier load such as, for example, with a capacitance between 1 pF, 10 pF, 100 pF, 1 nF, 10 nF, 100 nF, etc.

The RF driver 105 is coupled with a filter 140. In this example, the filter 140 includes a high pass filter. The high pass filter can include a high-pass capacitor 705 and a high-pass inductor 710. The high-pass capacitor 705 may be coupled in series with the RF driver 105 and the high-pass inductor 710 may be coupled to the RF driver 105 and ground.

The nanosecond pulser bias generator 115 is coupled with a filter 145. In this example, the filter 145 includes a low-pass filter. The low-pass filter can include a low-pass capacitor 720 and a low-pass inductor 715. The low-pass inductor 715 may be coupled in series with the nanosecond pulser bias generator 115 and the low-pass capacitor 720 may be coupled to the nanosecond pulser bias generator 115 and ground.

In some embodiments, the filter 140 may include a high-pass filter such as, for example, a high-pass capacitor 705 placed in series with the RF driver 105 and/or a high-pass inductor 710 connected to ground. The high-pass inductor 710 may, for example, include an inductor with an inductance of about 20 nH to about 50 μH. As another example, the high-pass inductor 710 may include a high-pass inductor 710 with an inductance of about 200 nH to about 5 μH. As another example, the high-pass inductor 710 may include an inductor with an inductance of about 500 nH to about 1 μH. As another example, the a high-pass inductor 710 may include an inductor with an inductance of about 800 nH.

The high-pass capacitor 705 may, for example, include an capacitor with an capacitance of about 10 pF to about 10 nF. As another example, the high-pass capacitor 705 may include a high-pass capacitor 705 with an capacitance of about 50 pF to about 1 nF. As another example, the high-pass capacitor 705 may include an capacitor with an capacitance of about 100 pF to about 500 pF. As another example, the a high-pass may include an capacitor with an capacitance of about 320 pF.

In some embodiments, the filter 145 may include a low-pass filter such as, for example, a low-pass inductor 715 placed in series with the nanosecond pulser bias generator 115 and/or a low-pass capacitor 720 connected to ground. The low-pass inductor 715 may, for example, include an inductor with an inductance of about 800 nH to about 500 μH. As another example, the low-pass inductor 715 may include a low-pass inductor 715 with an inductance of about 1 μH to about 100 μH. As another example, the low-pass inductor 715 may include an inductor with an inductance of about 1 μH to about 10 μH. As another example, the a low-pass may include an inductor with an inductance of about 2.5 μH.

The low-pass capacitor 720 may, for example, include an capacitor with an capacitance of about 10 pF to about 10 nF. As another example, the low-pass capacitor 720 may include a high-pass capacitor 705 with an capacitance of about 50 pF to about 1 nF. As another example, the low-pass capacitor 720 may include an capacitor with an capacitance of about 100 pF to about 500 pF. As another example, the a low-pass may include an capacitor with an capacitance of about 250 pF.

In some embodiments, either or both the low-pass inductor 715 and/or the high-pass inductor 710 may have a stray capacitance of less than about 250 pF. The connection between the RF driver 105 and the filter 145 may have a stray inductance of less than about 2.5 μH.

In some embodiments, the example shown in the plasma system 700 may have a 50 ohm characteristic impedance. In some embodiments, the example shown in the plasma system 700 may be operate at a frequency of about 5 MHz. In some embodiments, the example shown in the plasma system 700 may produces pulses with a pulse width of greater than about 100 ns.

FIG. 8 is a circuit diagram of an RF driver and chamber circuit 800 according to some embodiments.

In this example, the RF driver and chamber circuit 800 may include an RF driver 805. The RF driver 805, for example, may be a half-bridge driver or a full-bridge driver as shown in FIG. 8. The RF driver 805 may include an input voltage source V1 that may be a DC voltage source (e.g., a capacitive source, AC-DC converter, etc.). In some embodiments, the RF driver 805 may include four switches S1, S2, S3, and S4. In some embodiments, the RF driver 805 may include a plurality of switches S1, S2, S3, and S4 in series or in parallel. These switches S1, S2, S3, and S4, for example, may include any type of solid-state switch such as, for example, IGBTs, a MOSFETs, a SiC MOSFETs, SiC junction transistors, FETs, SiC switches, GaN switches, photoconductive switches, etc. These switches S1, S2, S3, and S4 may be switched at high frequencies and/or may produce a high voltage pulses. These frequencies may, for example, include frequencies of about 400 kHz, 0.5 MHz, 2.0 MHz, 4.0 MHz, 13.56 MHz, 27.12 MHz, 40.68 MHz, 50 MHz, etc.

Each switch of switches S1, S2, S3, and S4 may be coupled in parallel with a respective diode D1, D2, D3, and D4 and may include stray inductance represented by inductor L1, L2, L3, and L4. In some embodiments, the inductances of inductor L1, L2, L3, and L4 may be equal. In some embodiments, the inductances of inductor L1, L2, L3, and L4 may be less than about 50 nH, 100 nH, 150 nH, 500 nH, 1,000 nH, etc. The combination of a switch (S1, S2, S3, or S4) and a respective diode (D1, D2, D3, or D4) may be coupled in series with a respective inductor (L1, L2, L3, or L4). Inductors L3 and L4 are connected with ground. Inductor L1 is connected with switch S4 and the resonant circuit 810. And inductor L2 is connected with switch S3 and the opposite side of the resonant circuit 810.

In some embodiments, the RF driver 805 may be coupled with a resonant circuit 810. The resonant circuit 810 may include a resonant inductor L5 and/or a resonant capacitor C5 coupled with a transformer T1. The resonant circuit 810 may include a resonant resistance R5, for example, that may include the stray resistance of any leads between the RF driver 805 and the resonant circuit 810 and/or any component within the resonant circuit 810 such as, for example, the transformer T1, the capacitor C5, and/or the inductor L5. In some embodiments, the resonant resistance R5 comprises only stray resistances of wires, traces, or circuit elements. While the inductance and/or capacitance of other circuit elements may affect the driving frequency, the driving frequency can be set largely by choice of the resonant inductor L5 and/or the resonant capacitor C5. Further refinements and/or tuning may be required to create the proper driving frequency in light of stray inductance or stray capacitance. In addition, the rise time across the transformer T1 can be adjusted by changing L5 and/or C5, provided that:

$${f}_{resonant} = \frac{1}{2 π \sqrt{( L 5 ) ( C 2 )}} = constant .$$

In some embodiments, large inductance values for L5 can result in slower or shorter rise times. These values may also affect the burst envelope. As shown in FIG. 17, each burst can include transient and steady state pulses. The transient pulses within each burst may be set by L5 and/or the Q of the system until full voltage is reached during the steady state pulses.

If the switches in the RF driver 805 are switched at the resonant frequency, fᵣₑₛₒₙₐₙₜ, then the output voltage at the transformer T1 will be amplified. In some embodiments, the resonant frequency may be about 400 kHz, 0.5 MHz, 2.0 MHz, 4.0 MHz, 13.56 MHz, 27.12 MHz, 40.68 MHz, 50 MHz, etc.

In some embodiments, the resonant capacitor C5 may include the stray capacitance of the transformer T1 and/or a physical capacitor. In some embodiments, the resonant capacitor C5 may have a capacitance of about 10 μF, 1 μF, 100 nF, 10 nF, etc. In some embodiments, the resonant inductor L5 may include the stray inductance of the transformer T1 and/or a physical inductor. In some embodiments, the resonant inductor L5 may have an inductance of about 50 nH, 100 nH, 150 nH, 500 nH, 1,000 nH, etc. In some embodiments, the resonant resistor R5 may have a resistance of about 10 ohms, 25 ohms, 50 ohms, 100 ohms, 150 ohms, 500 ohms, etc.

In some embodiments, the resonant resistor R5 may represent the stray resistance of wires, traces, and/or the transformer windings within the physical circuit. In some embodiments, the resonant resistor R5 may have a resistance of about 10 mohms, 50 mohms, 100 mohms, 200 mohms, 500 mohms, etc.

In some embodiments, the transformer T1 may comprise a transformer as disclosed in U.S. patent application Ser. No. 15/365,094, titled “High Voltage Transformer,” which is incorporated into this document for all purposes. In some embodiments, the output voltage of the resonant circuit 810 can be changed by changing the duty cycle (e.g., the switch “on” time or the time a switch is conducting) of switches S1, S2, S3, and/or S4. For example, the longer the duty cycle, the higher the output voltage; and the shorter the duty cycle, the lower the output voltage. In some embodiments, the output voltage of the resonant circuit 810 can be changed or tuned by adjusting the duty cycle of the switching in the RF driver 805.

For example, the duty cycle of the switches can be adjusted by changing the duty cycle of signal Sig1, which opens and closes switch S1; changing the duty cycle of signal Sig2, which opens and closes switch S2; changing the duty cycle of signal Sig3, which opens and closes switch S3; and changing the duty cycle of signal Sig4, which opens and closes switch S4. By adjusting the duty cycle of the switches S1, S2, S3, or S4, for example, the output voltage of the resonant circuit 810 can be controlled.

In some embodiments, each switch S1, S2, S3, or S4 in the RF driver 805 can be switched independently or in conjunction with one or more of the other switches. For example, the signal Sig1 may be the same signal as signal Sig3. As another example, the signal Sig2 may be the same signal as signal Sig4. As another example, each signal may be independent and may control each switch S1, S2, S3, or S4 independently or separately.

In some embodiments, the resonant circuit 810 may be coupled with a half-wave rectifier 815 that may include a blocking diode D7.

In some embodiments, the half-wave rectifier 815 may be coupled with the resistive output stage 820. The resistive output stage 820 may include any resistive output stage known in the art. For example, the resistive output stage 820 may include any resistive output stage described in U.S. patent application Ser. No. 16/178,538 titled “HIGH VOLTAGE RESISTIVE OUTPUT STAGE CIRCUIT,” which is incorporated into this disclosure in its entirety for all purposes.

For example, the resistive output stage 820 may include an inductor L11, resistor R3, resistor R1, and capacitor C11. In some embodiments, inductor L11 may include an inductance of about 5 μH to about 25 μH. In some embodiments, the resistor R1 may include a resistance of about 50 ohms to about 250 ohms. In some embodiments, the resistor R3 may comprise the stray resistance in the resistive output stage 820.

In some embodiments, the resistor R1 may include a plurality of resistors arranged in series and/or parallel. The capacitor C11 may represent the stray capacitance of the resistor R1 including the capacitance of the arrangement series and/or parallel resistors. The capacitance of stray capacitance C11, for example, may be less than 500 pF, 250 pF, 100 pF, 50 pF, 10 pF, 1 pF, etc. The capacitance of stray capacitance C11, for example, may be less than the load capacitance such as, for example, less than the capacitance of C7, C8, and/or C9.

In some embodiments, the resistor R1 may discharge the load (e.g., a plasma sheath capacitance). In some embodiments, the resistive output stage 820 may be configured to discharge over about 1 kilowatt of average power during each pulse cycle and/or a joule or less of energy in each pulse cycle. In some embodiments, the resistance of the resistor R1 in the resistive output stage 820 may be less than 200 ohms. In some embodiments, the resistor R1 may comprise a plurality of resistors arranged in series or parallel having a combined capacitance less than about 200 pF (e.g., C11).

In some embodiments, the resistive output stage 820 may include a collection of circuit elements that can be used to control the shape of a voltage waveform on a load. In some embodiments, the resistive output stage 820 may include passive elements only (e.g., resistors, capacitors, inductors, etc.). In some embodiments, the resistive output stage 820 may include active circuit elements (e.g., switches) as well as passive circuit elements. In some embodiments, the resistive output stage 820, for example, can be used to control the voltage rise time of a waveform and/or the voltage fall time of waveform.

In some embodiments, the resistive output stage 820 can discharge capacitive loads (e.g., a wafer and/or a plasma). For example, these capacitive loads may have small capacitance (e.g., about 10 pF, 100 pF, 500 pF, 1 nF, 10 nF, 100 nF, etc.).

In some embodiments, a resistive output stage can be used in circuits with pulses having a high pulse voltage (e.g., voltages greater than 1 kV, 10 kV, 20 kV, 50 kV, 100 kV, etc.) and/or high frequencies (e.g., frequencies greater than 1 kHz, 10 kHz, 100 kHz, 200 kHz, 500 kHz, 1 MHz, etc.) and/or frequencies of about 400 kHz, 0.5 MHz, 2.0 MHz, 4.0 MHz, 13.56 MHz, 27.12 MHz, 40.68 MHz, 50 MHz, etc.

In some embodiments, the resistive output stage may be selected to handle high average power, high peak power, fast rise times and/or fast fall times. For example, the average power rating might be greater than about 0.5 kW, 1.0 kW, 10 kW, 25 kW, etc., and/or the peak power rating might be greater than about 1 kW, 10 kW, 100 kW, 1 MW, etc.

In some embodiments, the resistive output stage 820 may include a series or parallel network of passive components. For example, the resistive output stage 820 may include a series of a resistor, a capacitor, and an inductor. As another example, the resistive output stage 820 may include a capacitor in parallel with an inductor and the capacitor-inductor combination in series with a resistor. For example, L11 can be chosen large enough so that there is no significant energy injected into the resistive output stage when there is voltage out of the rectifier. The values of R3 and R1 can be chosen so that the L/R time can drain the appropriate capacitors in the load faster than the RF frequency

In some embodiments, the resistive output stage 820 may be coupled with the bias compensation circuit 825. The bias compensation circuit 825 may include any bias and/or bias compensation circuit known in the art. For example, the bias compensation circuit 825 may include any bias and/or bias compensation circuit described in U.S. patent application Ser. No. 16/523,840 titled “NANOSECOND PULSER BIAS COMPENSATION,” which is incorporated into this disclosure in its entirety for all purposes. In some embodiments, the resistive output stage 820 and/or the bias compensation circuit 825 may be optional.

In some embodiments, a nanosecond pulser may include a resistive output stage that is similar to the resistive output stage 820.

In some embodiments, the bias compensation circuit 825 may include a bias capacitor C11, blocking capacitor C12, a blocking diode D8, switch S5 (e.g., a high voltage switch), offset supply voltage V2, resistance R2, and/or resistance R4. In some embodiments, the switch S5 comprises a high voltage switch described in U.S. Patent Application No. 82/717,637, titled “HIGH VOLTAGE SWITCH FOR NANOSECOND PULSING,” and/or in U.S. patent application Ser. No. 16/178,565, titled “HIGH VOLTAGE SWITCH FOR NANOSECOND PULSING,” which is incorporated into this disclosure in its entirety for all purposes.

In some embodiments, the offset supply voltage V5 may include a DC voltage source that can bias the output voltage either positively or negatively. In some embodiments, the blocking capacitor C12 may isolate/separate the offset supply voltage V2 from the resistive output stage 820 and/or other circuit elements. In some embodiments, the bias compensation circuit 825 may allow for a potential shift of power from one portion of the circuit to another. In some embodiments, the bias compensation circuit 825 may be used to hold a wafer in place as high voltage pulses are active within the chamber. Resistance R2 may protect/isolate the DC bias supply from the driver.

In some embodiments, the switch S5 may be open while the RF driver 805 is pulsing and closed when the RF driver 805 is not pulsing. While closed, the switch S5 may, for example, short current across the blocking diode D8. Shorting this current may allow the bias between the wafer and the chuck to be less than 2 kV, which may be within acceptable tolerances.

In some embodiments, the plasma and chamber 830 may be coupled with the bias compensation circuit 825. The plasma and chamber 830, for example, may be represented by the various circuit elements shown in FIG. 8.

FIG. 9 is a circuit diagram of an RF driver and chamber circuit 900 according to some embodiments. The RF driver and chamber circuit 900, for example, may include the RF driver 805, the resonant circuit 810, the bias compensation circuit 825, and the plasma and chamber 830. The RF driver and chamber circuit 900 is similar to the RF driver and chamber circuit 800 but without the resistive output stage 820 and includes an energy recovery circuit 905. In some embodiments, the energy recovery circuit 905 and/or the bias compensation circuit 825 may be optional.

In this example, the energy recovery circuit 905 may be positioned on or electrically coupled with the secondary side of the transformer T1. The energy recovery circuit 905, for example, may include a diode D9 (e.g., a crowbar diode) across the secondary side of the transformer T1. The energy recovery circuit 905, for example, may include diode D10 and inductor L12 (arranged in series), which can allow current to flow from the secondary side of the transformer T1 to charge the power supply C1 and current to flow to the plasma and chamber 830. The diode D12 and the inductor L12 may be electrically connected with the secondary side of the transformer T1 and coupled with the power supply C1. In some embodiments, the energy recovery circuit 905 may include diode D13 and/or inductor L13 electrically coupled with the secondary of the transformer T1. The inductor L12 may represent the stray inductance and/or may include the stray inductance of the transformer T1.

When the nanosecond pulser is turned on, current may charge the plasma and chamber 830 (e.g., charge the capacitor C7, capacitor C8, or capacitor C9). Some current, for example, may flow through inductor L12 when the voltage on the secondary side of the transformer T1 rises above the charge voltage on the power supply C1. When the nanosecond pulser is turned off, current may flow from the capacitors within the plasma and chamber 830 through the inductor L12 to charge the power supply C1 until the voltage across the inductor L12 is zero. The diode D9 may prevent the capacitors within the plasma and chamber 830 from ringing with the inductance in the plasma and chamber 830 or the bias compensation circuit 825.

The diode D12 may, for example, prevent charge from flowing from the power supply C1 to the capacitors within the plasma and chamber 830.

The value of inductor L12 can be selected to control the current fall time. In some embodiments, the inductor L12 can have an inductance value between 1 μH-500 μH.

In some embodiments, the energy recovery circuit 905 may include a switch that can be used to control the flow of current through the inductor L12. The switch, for example, may be placed in series with the inductor L12. In some embodiments, the switch may be closed when the switch S1 is open and/or no longer pulsing to allow current to flow from the plasma and chamber 830 back to the power supply C1.

A switch in the energy recovery circuit 905, for example, may include a high voltage switch such as, for example, the high voltage switch disclosed in U.S. patent application Ser. No. 16/178,565 filed Nov. 1, 2018, titled “HIGH VOLTAGE SWITCH WITH ISOLATED POWER,” which claims priority to U.S. Provisional Patent Application No. 62/717,637 filed Aug. 10, 2018, both of which are incorporated by reference in the entirety. In some embodiments, the RF driver 805 may include a high voltage switch in place of or in addition to the various components shown in RF driver 805. In some embodiments, using a high voltage switch may allow for removal of at least the transformer T1 and the switch S1.

In some embodiments, a nanosecond pulser may include an energy recovery circuit similar to the energy recover circuit 905.

The RF driver and chamber circuit 800 and the RF driver and chamber circuit 900 do not include a traditional matching network such as, for example, a 50 ohm matching network or an external matching network or standalone matching network. Indeed, the embodiments described within this document do not require a 50 ohm matching network to tune the switching power applied to the wafer chamber. In addition, embodiments described within this document provide a variable output impedance RF generator without a traditional matching network. This can allow for rapid changes to the power drawn by the plasma chamber. Typically, this tuning of the matching network can take at least 100 μs-200 μs. In some embodiments, power changes can occur within one or two RF cycles, for example, 2.5 μs-5.0 μs at 400 kHz.

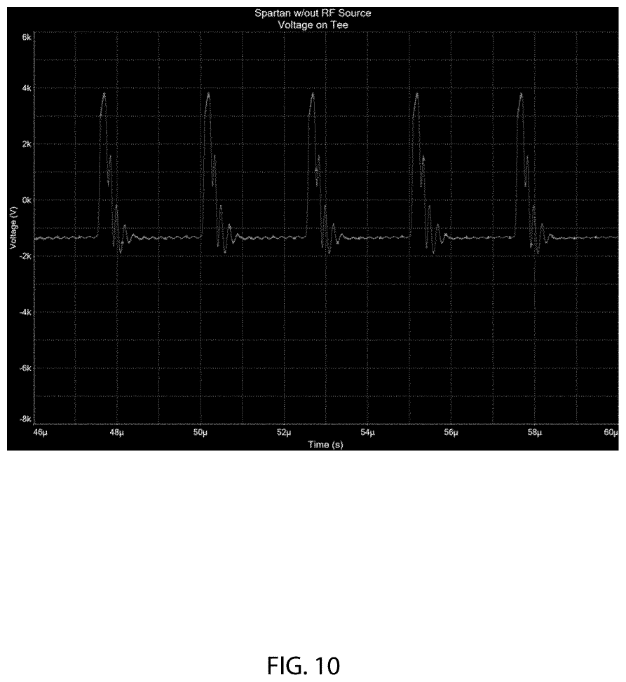

FIG. 10 is a waveform produced by a plasma system such as, for example, plasma system 300, 400, 500, 600, or 700. The waveform shows the voltage prior to chamber. In this example, the waveform is produced with the RF driver 105 turned off. In this example, a plurality of pulses are produced.

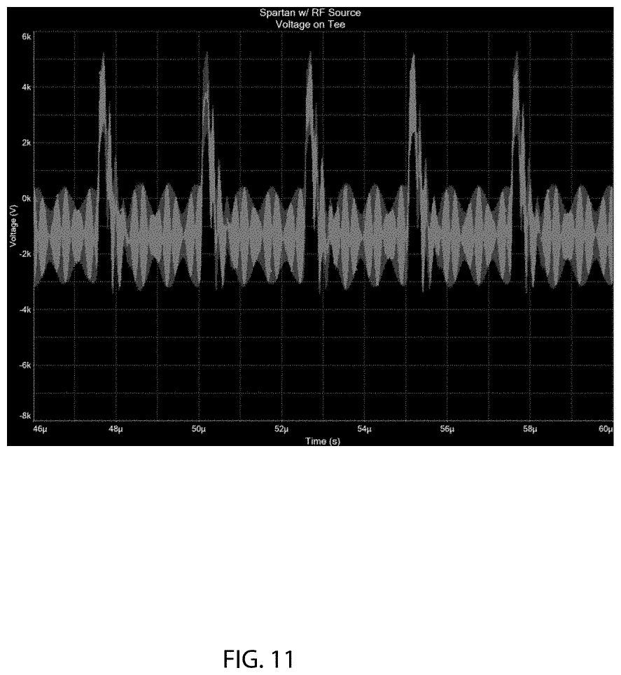

FIG. 11 is a waveform produced by a plasma system such as, for example, plasma system 300, 400, 500, 600, or 700. The waveform shows the voltage prior to chamber. In this example, the both the RF driver 105 and the nanosecond pulser bias generator 115 are turned on. In this example, a plurality of pulses are produced as well as an RF signal.

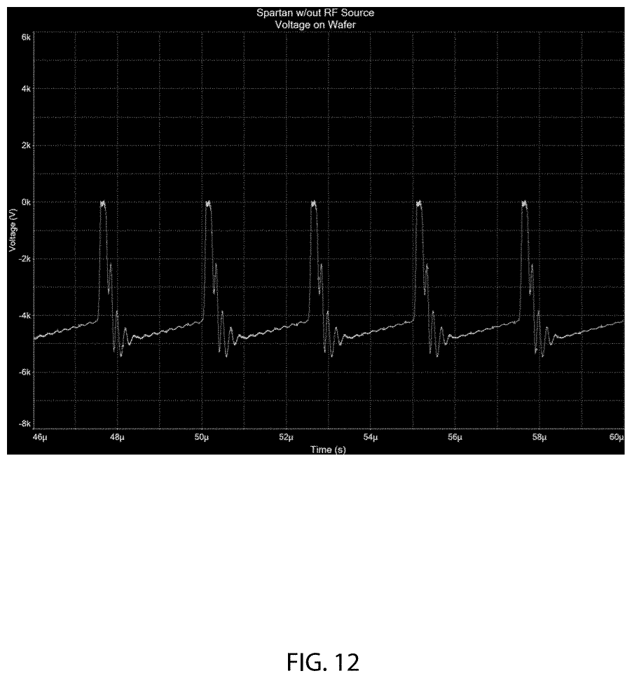

FIG. 12 is a waveform produced by a plasma system such as, for example, plasma system 300, 400, 500, 600, or 700. The waveform shows the within the chamber such as, for example, at the wafer. In this example, the waveform is produced with the RF driver 105 turned off. In this example, a plurality of pulses are produced.

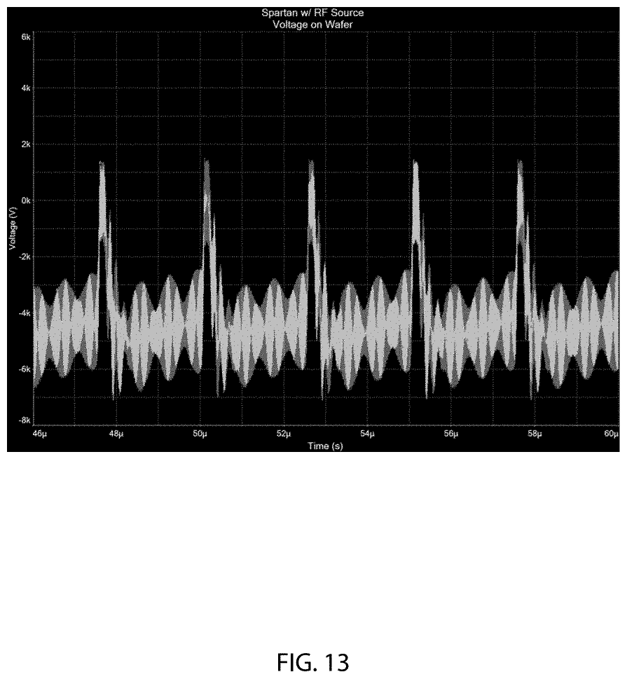

FIG. 13 is a waveform produced by a plasma system such as, for example, plasma system 300, 400, 500, 600, or 700. The waveform shows the within the chamber such as, for example, at the wafer. In this example, the waveform is produced with the RF driver 105 turned off. In this example, a plurality of pulses are produced.

The term “or” is inclusive.

Unless otherwise specified, the term “substantially” means within 5% or 10% of the value referred to or within manufacturing tolerances. Unless otherwise specified, the term “about” means within 5% or 10% of the value referred to or within manufacturing tolerances.

Some portions are presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm is a self-consistent sequence of operations or similar processing leading to a desired result. In this context, operations or processing involves physical manipulation of physical quantities. Typically, although not necessarily, such quantities may take the form of electrical or magnetic signals capable of being stored, transferred, combined, compared or otherwise manipulated. It has proven convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

The system or systems discussed herein are not limited to any particular hardware architecture or configuration. A computing device can include any suitable arrangement of components that provides a result conditioned on one or more inputs. Suitable computing devices include multipurpose microprocessor-based computer systems accessing stored software that programs or configures the computing system from a general-purpose computing apparatus to a specialized computing apparatus implementing one or more embodiments of the present subject matter. Any suitable programming, scripting, or other type of language or combinations of languages may be used to implement the teachings contained herein in software to be used in programming or configuring a computing device.

Embodiments of the methods disclosed herein may be performed in the operation of such computing devices. The order of the blocks presented in the examples above can be varied—for example, blocks can be re-ordered, combined, and/or broken into sub-blocks. Some blocks or processes can be performed in parallel.

The use of “adapted to” or “configured to” is meant as open and inclusive language that does not foreclose devices adapted to or configured to perform additional tasks or steps. Additionally, the use of “based on” is meant to be open and inclusive, in that a process, step, calculation, or other action “based on” one or more recited conditions or values may, in practice, be based on additional conditions or values beyond those recited. Headings, lists, and numbering are for ease of explanation only and are not meant to be limiting.

While the present subject matter has been described in detail with respect to specific embodiments thereof, it will be appreciated that those skilled in the art, upon attaining an understanding of the foregoing, may readily produce alterations to, variations of, and equivalents to such embodiments. Accordingly, it should be understood that the present disclosure has been presented for purposes of example rather than limitation, and does not preclude inclusion of such modifications, variations and/or additions to the present subject matter as would be readily apparent to one of ordinary skill in the art.

That which is claimed:

1. A plasma system comprising:
a plasma chamber;
an RF driver driving RF bursts into the plasma chamber with an RF frequency greater than 2 MHz;
a nanosecond pulser driving pulses into the plasma chamber with a pulse repetition frequency and a peak voltage, the pulse repetition frequency being less than the RF frequency and the peak voltage being greater than 2 kV;
a first filter disposed between the RF driver and the plasma chamber; and
a second filter disposed between the nanosecond pulser and the plasma chamber.

2. The plasma system according to claim 1, wherein the pulse repetition frequency is greater than 10 kHz.

3. The plasma system according to claim 1, wherein first filter includes a capacitor in series with the RF driver and the plasma chamber, the capacitor includes a capacitance less than about 500 pH.

4. The plasma system according to claim 1, wherein first filter includes an inductor coupled with an output of the RF driver and ground.

5. The plasma system according to claim 1, wherein the second filter includes an inductor in series with the nanosecond pulser and the plasma chamber, the inductor having an inductance less than about 50 μH.

6. The plasma system according to claim 1, wherein the second filter includes a capacitor in coupled with an output of the nanosecond pulser and ground.

7. The plasma system according to claim 1, wherein the first filter comprises a high pass filter.

8. The plasma system according to claim 1, wherein the second filter comprises a low pass filter.

9. The plasma system according to claim 1, wherein the RF driver does not include a matching network.

10. The plasma system according to claim 1, wherein the plasma chamber comprises an antenna electrically coupled with the RF driver.

11. The plasma system according to claim 1, wherein the plasma chamber comprises a cathode electrically coupled with the RF driver.

12. The plasma system according to claim 1, wherein the plasma chamber comprises a cathode electrically coupled with the nanosecond pulser.

13. A plasma system comprising:
a plasma chamber comprising an antenna and a cathode;
an RF driver electrically coupled with the antenna, the RF driver producing RF bursts in the plasma chamber with an RF frequency greater than about 2 MHz;
a nanosecond pulser electrically coupled with the cathode, the nanosecond pulser producing pulses into the plasma chamber with a pulse repetition frequency less than the RF frequency and with a voltage greater than 2 kV;
a capacitor disposed between the RF driver and the antenna; and
an inductor disposed between the nanosecond pulser and the cathode.

14. The plasma system according to claim 13, wherein the capacitor has a capacitance less than about 100 pF.

15. The plasma system according to claim 13, wherein the inductor has an inductance less than about 10 nH.

16. The plasma system according to claim 13, wherein the pulse repetition frequency is greater than 10 kHz.

17. A plasma system comprising:
a plasma chamber comprising a cathode;
an RF driver electrically coupled with the cathode, the RF driver producing RF bursts in the plasma chamber with an RF frequency greater than about 2 MHz;
a nanosecond pulser electrically coupled with the cathode, the nanosecond pulser producing pulses into the plasma chamber with a pulse repetition frequency less than the RF frequency and with a voltage greater than 2 kV;
a capacitor disposed between the RF driver and the cathode; and
an inductor disposed between the nanosecond pulser and the cathode.

18. The plasma system according to claim 17, wherein the capacitor has a capacitance less than about 100 pF.

19. The plasma system according to claim 17, wherein the inductor has an inductance less than about 10 nH.

20. The plasma system according to claim 17, wherein the pulse repetition frequency is greater than 10 kHz.
